(19) United States
(12) Patent Application Publication
(10) Pub. No.: US 2015/0253680 A1
(43) Pub. Date: Sep. 10, 2015

(54) METHOD OF CALCULATING AMOUNT OF ABERRATION AND METHOD OF CALCULATING AMOUNT OF MISALIGNMENT

(71) Applicant: Kabushiki Kaisha Toshiba, Minato-ku (JP)

(72) Inventors: Kazufumi Shiozawa, Yokohama (JP); Sayaka Tamaoki, Yokohama (JP)

(73) Assignee: Kabushiki Kaisha Toshiba, Minato-ku (JP)

(21) Appl. No.: 14/483,368

(22) Filed: Sep. 11, 2014

(30) Foreign Application Priority Data
Mar. 7, 2014 (JP) 2014-045224

(51) Int. Cl. G03F 7/20

(52) U.S. Cl. CPC G03F 7/70641

(57) ABSTRACT

A method of calculating the amount of aberration is provided according to an embodiment. In the method of calculating the amount of aberration, a simulation is performed to calculate for each Zernike term the aberration sensitivity of an aberration that is generated on a substrate when a lithography tool performs exposure processing on the substrate by using a mask on which a mask pattern is formed. A substrate pattern corresponding to the mask pattern is formed on the substrate by using the lithography tool. The amount of misalignment of the substrate pattern is then measured. Moreover, the amount of aberration for each Zernike term is calculated on the basis of the aberration sensitivity and the amount of misalignment.

### CROSS-REFERENCE TO RELATED APPLICATIONS

This application is based upon and claims the benefit of priority from Japanese Patent Application No. 2014-045224, filed on Mar. 7, 2014; the entire contents of which are incorporated herein by reference.

### FIELD

Embodiments described herein relate generally to a method of calculating an amount of aberration and a method of calculating an amount of misalignment.

### BACKGROUND

A body pattern (a circuit pattern) on an upper layer side and a body pattern on a lower layer side of a wafer are aligned when a semiconductor device is manufactured. The alignment is performed by measuring the amount of misalignment between an alignment mark formed on the upper layer side of the wafer and an alignment mark formed on the lower layer side of the wafer.

In a lithography process where an aberration is generated, however, the misalignment sensitivity of a pattern is different between the alignment mark and the body pattern. It has thus been unable to measure an accurate amount of misalignment in the misalignment measurement which uses the alignment mark in the related art. Accordingly, it is desired to find the amount of aberration with ease and accuracy.

### BRIEF DESCRIPTION OF THE DRAWINGS

FIG. 1 is a diagram illustrating a configuration of a lithography tool;

FIG. 2 is a diagram illustrating a position at which a mask pattern is arranged;

FIGS. 3A and 3B are diagrams each illustrating a body pattern;

FIG. 4 is a diagram illustrating a first configuration example of an aberration monitoring pattern;

FIG. 5 is a diagram illustrating a configuration example of an alignment mark;

FIG. 6 is a diagram illustrating a Zernike polynomial;

FIG. 7 is a flowchart illustrating a procedure of a process of calculating the amount of misalignment;

FIGS. 8A and 8B are diagrams each illustrating another configuration example of the aberration monitoring pattern;

FIG. 9 is a diagram illustrating the form of lighting included in the lithography tool;

FIG. 10 is a diagram illustrating an example of a dimension of the aberration monitoring pattern; and

FIGS. 11A to 11D are diagrams each illustrating the aberration sensitivity for each pattern.

### DETAILED DESCRIPTION

A method of calculating the amount of aberration is provided according to the present embodiment. In the method of calculating the amount of aberration, the aberration sensitivity of an aberration is calculated for each Zernike term by simulation, the aberration being generated on a substrate when a lithography tool performs exposure processing on the substrate by using a mask on which a mask pattern is formed. Moreover, a substrate pattern corresponding to the mask pattern is formed on the substrate by using the lithography tool. The amount of misalignment of the substrate pattern is then measured. Furthermore, the amount of aberration is calculated for each Zernike term on the basis of the aberration sensitivity and the amount of misalignment.

The method of calculating the amount of aberration and the method of calculating the amount of misalignment according to embodiments will be explained below in detail with reference to the accompanying drawings. The present invention is not limited to the following embodiments.

### Embodiments

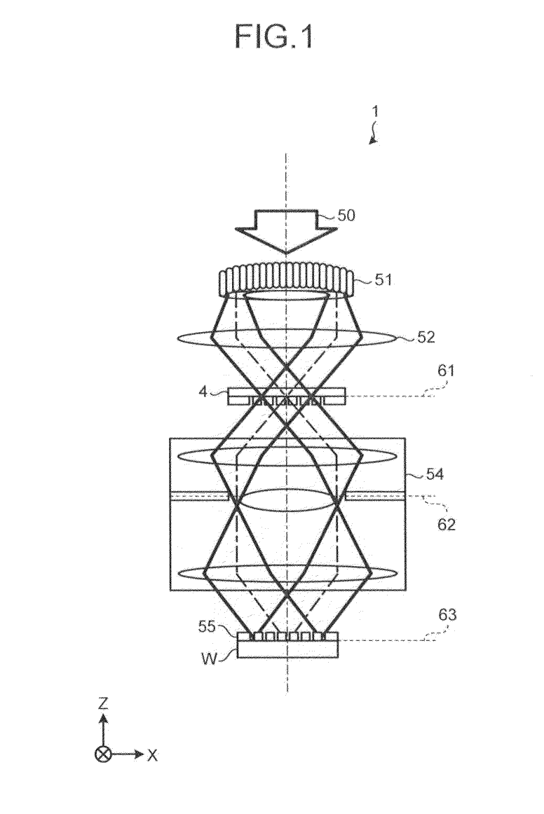

FIG. 1 is a diagram illustrating a configuration of a lithography tool. FIG. 1 is a schematic illustration of a lithography tool 1. The lithography tool (exposure apparatus) 1 uses a DUV laser beam 50 or the like as exposure light. Note that the lithography tool 1 may use exposure light other than the DUV laser beam 50 but, in the present embodiment, there will be described a case where the lithography tool 1 uses the DUV laser beam 50.

The lithography tool 1 includes a fly's eye lens 51, a condenser lens 52, and a projection lens system 54. The fly's eye lens 51 makes the brightness of the DUV laser beam 50 uniform and then transmits the laser beam to the condenser lens 52. The condenser lens 52 condenses the DUV laser beam 50 and then transmits the laser beam to a mask 4.

The mask 4 is a transmissive mask on which a mask pattern is formed. In the present embodiment, the mask 4 is used to form a body pattern (a circuit pattern), an alignment mark, and an aberration monitoring pattern (to be described) on a substrate (such as a wafer W). Accordingly, there are formed on the mask 4 a mask pattern corresponding to the body pattern (the circuit pattern), a mask pattern corresponding to the alignment mark, and a mask pattern corresponding to the aberration monitoring pattern. The DUV laser beam 50 radiated onto the mask 4 is transmitted to the projection lens system 54.

The projection lens system 54 includes a lens and the like. The projection lens system 54 projects the DUV laser beam 50 diffracted by the mask 4 onto the wafer W. A resist 55 is applied on the wafer W. The resist 55 on the wafer W is irradiated with the DUV laser beam 50 that is transmitted through the mask 4.

In the lithography tool 1, the DUV laser beam 50 output from a light source (not shown) is radiated onto the mask 4 through the fly's eye lens 51 and the condenser lens 52. The DUV laser beam 50 radiated onto the mask 4 is then radiated onto the wafer W through the projection lens system 54 so that the resist 55 is exposed. As a result, an optical image (an aerial image) in accordance with the mask pattern is formed on the resist 55.

In the lithography tool 1, the DUV laser beam 50 emitted from the fly's eye lens 51 serves as a secondary light source, while a mask pattern surface of the mask 4 serves as an object surface 61. A pupil surface 62 is formed within the projection lens system 54, and the resist 55 serves as an image surface 63.

The DUV laser beam 50 emitted from the fly's eye lens 51 has a light luminance distribution and a polarization property. Moreover, the DUV laser beam 50 on the pupil surface 62 has a pupil transmittance distribution for a V polarization property and a pupil transmittance distribution for an H polarization property.

Therefore, a pattern misalignment on the wafer W caused by the aberration is generated on the wafer W. As a consequence, the misalignment sensitivity differs between the alignment mark and the body pattern on the wafer W. The present embodiment uses the aberration monitoring pattern (a mask pattern) on the mask 4 and the aberration monitoring pattern (a wafer pattern) on the wafer W to calculate the amount of aberration. Then, the amount of aberration is used to calculate the amount of misalignment (amount of positional displacement) of the body pattern on the wafer.

Note that there will be described below a case where a direction of the DUV laser beam 50 radiated onto the wafer W (direction perpendicular to a top surface of the wafer W) corresponds to a Z direction, and the wafer W is exposed while disposed in a direction parallel to an XY plane.

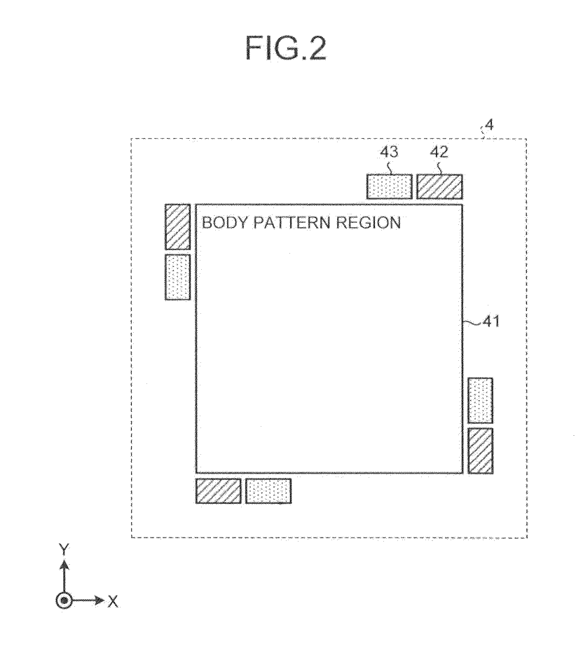

FIG. 2 is a diagram illustrating a position at which the mask pattern is arranged. The mask pattern is formed on the mask 4 that is used to form a semiconductor device. The mask pattern includes a mask pattern of the body pattern, a mask pattern of the alignment mark, a mask pattern of the aberration monitoring pattern, and the like.

The body pattern, the alignment mark, and the aberration monitoring pattern for an upper layer are formed as the mask pattern on the mask 4 that is used in forming the pattern on the upper layer side of the wafer, for example. The body pattern, the alignment mark, and the aberration monitoring pattern for a lower layer are formed as the mask pattern on the mask 4 that is used in forming the wafer pattern on the lower layer side.

The wafer pattern corresponding to the mask pattern is formed on the wafer W when the lithography tool 1 exposes the wafer W by using the mask 4. The body pattern, the alignment mark, and the aberration monitoring pattern that are used as the mask pattern are hereinafter referred to as the body pattern of the mask 4, the alignment mark of the mask 4, and the aberration monitoring pattern of the mask 4, respectively. Moreover, each of the body pattern, the alignment mark, and the aberration monitoring pattern indicates the wafer pattern in the description.

The alignment mark is the wafer pattern used in performing the alignment between the pattern on the lower layer side (such as the wafer pattern after etching) and the pattern on the upper layer side (such as a resist pattern). When the lithography tool 1 is used to form the pattern on the upper layer side, the exposure of the pattern on the upper layer side is performed to not generate a misalignment with the pattern on the lower layer side.

The aberration monitoring pattern is the wafer pattern used in finding an aberration that is generated on the wafer W when the lithography tool 1 performs the exposure. The aberration changes depending on a state of the lithography tool 1, the mask pattern (arrangement or density thereof) formed on the mask 4, and the form of lighting of the light source radiating the DUV laser beam 50.

The body pattern as the mask pattern is arranged within a body pattern region 41 of the mask 4. The alignment mark as the mask pattern is arranged within an alignment mark region 42 of the mask 4, and the aberration monitoring pattern as the mask pattern is arranged within an aberration monitoring pattern region 43 of the mask 4.

The body pattern region 41 is arranged at the center of the mask 4, for example. The alignment mark region 42 and the aberration monitoring pattern region 43 are arranged on the outer peripheral portion of the mask 4 (outside the body pattern region 41), for example.

The alignment mark and the body pattern are arranged at the different positions on the mask 4 as described above. Moreover, the alignment mark and the body pattern have different forms on the mask 4. Furthermore, the pattern arranged around each of the alignment mark and the body pattern is different on the mask 4, whereby the alignment mark and the body pattern on the wafer W are affected by the aberration. As a result, the amount of misalignment on the wafer W measured at the alignment mark differs from the actual amount of misalignment of the body pattern.

What is calculated in the present embodiment is the amount of aberration affecting the magnitude of the amount of misalignment. The calculated amount of aberration is used to calculate the amount of misalignment between the alignment mark and the body pattern. The lithography tool 1 then performs the exposure processing of the pattern on the upper layer side on the basis of the calculated amount of misalignment.

Specifically, there are calculated the amount of misalignment between the alignment mark and the body pattern on the lower layer side and the amount of misalignment between the alignment mark and the body pattern on the upper layer side. The misalignment between the body pattern on the upper layer side and the body pattern on the lower layer side is then calculated on the basis of the calculated amounts of misalignment. Furthermore, the pattern on the upper layer side is formed such that the misalignment is not generated between the body pattern on the upper layer side and the body pattern on the lower layer side, on the basis of the calculated misalignment between the body pattern on the upper layer side and the body pattern on the lower layer side.

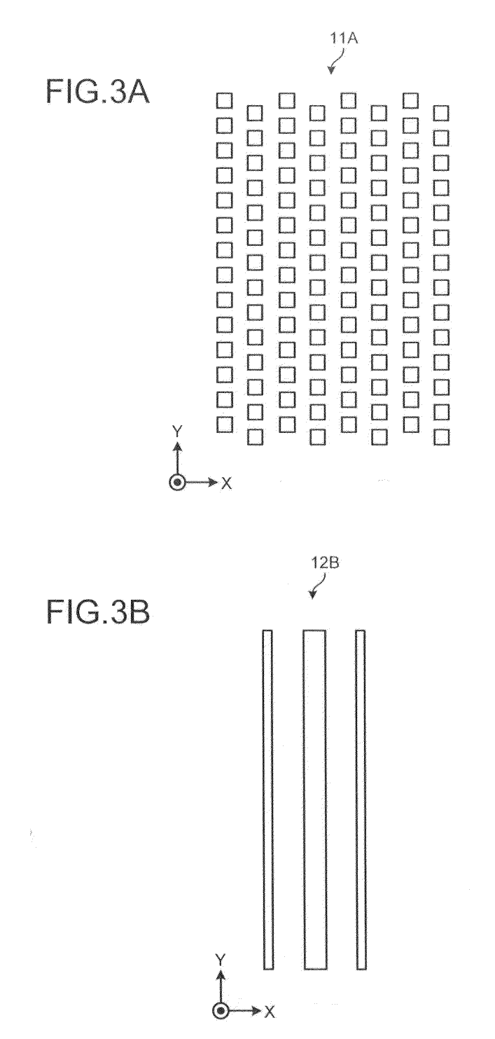

FIGS. 3A and 3B are diagrams each illustrating the body pattern. FIG. 3A illustrates a top view of a cell pattern 11A, while FIG. 3B illustrates a top view of a line pattern 12B. The cell pattern 11A corresponds to the body pattern on the lower layer side, while the line pattern 12B corresponds to the body pattern on the upper layer side, for example. In this case, the cell pattern 11A is formed on the wafer W first, and then the line pattern 12B having a hole shape (concave shape) is formed on top of the cell pattern 11A.

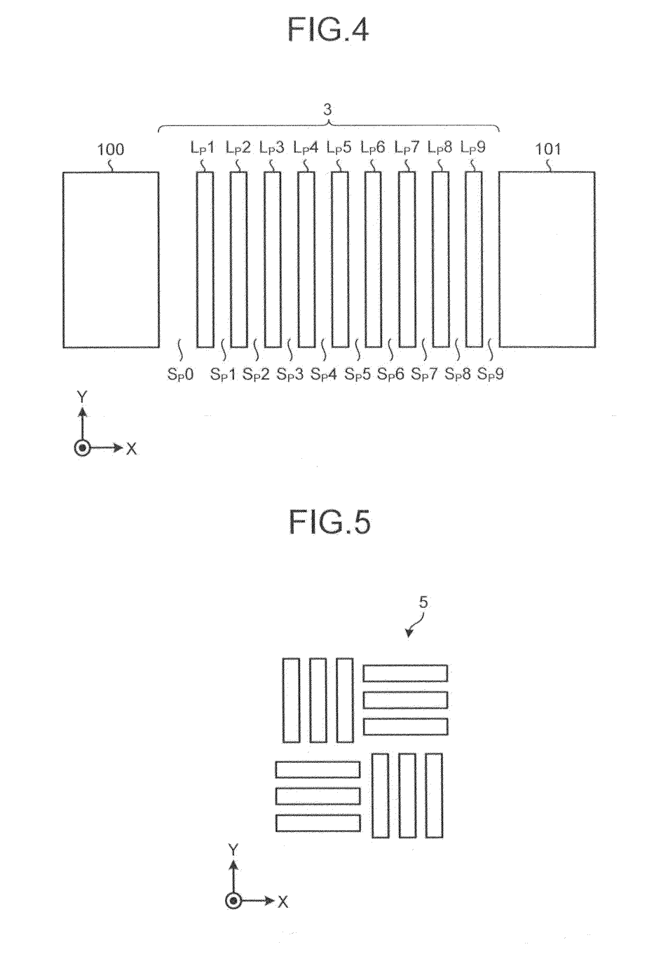

FIG. 4 is a diagram illustrating a first configuration example of the aberration monitoring pattern. An aberration monitoring pattern 3 is arranged between line patterns 100 and 101 that are thicker than each of line patterns Lp1 to Lp9 and space patterns Sp0 to Sp9, for example.

Within Zernike polynomials Z₁ to Z₈₁, 19 Zernike terms have an effect on the pattern misalignment. The present embodiment is thus adapted to configure the aberration monitoring pattern 3 to be able to measure 19 types of the amount of misalignment or dimensional gap of the pattern.

The aberration monitoring pattern 3 in this case includes nine of the line patterns Lp1 to Lp9 and 10 of the space patterns Sp0 to Sp9. The 19 Zernike terms are calculated on the basis of the 19 types of the amount of pattern misalignment.

The amount of misalignment of the line pattern Lp1 is affected by the 19 Zernike terms, for example. Accordingly, there is established an equation expressing the relation between the actual amount of misalignment of the line pattern Lp1 and the 19 Zernike terms. Likewise, there is established an equation expressing the relation between the actual amount of misalignment of each of the line patterns Lp2 to Lp9 and the space patterns Sp0 to Sp9, and the 19 Zernike terms. With the 19 equations being established, each of the 19 Zernike terms can be calculated on the basis of 19 simultaneous equations (simultaneous linear equations with 19 unknowns).

FIG. 5 is a diagram illustrating a configuration example of the alignment mark. An alignment mark 5 includes a pattern arranged side by side in an X direction and a pattern arranged side by side in a Y direction, for example. The alignment mark is formed by using the pattern on the lower layer side in advance when manufacturing the semiconductor device.

In the present embodiment, the pattern on the upper layer side is formed on the basis of the amount of misalignment between the body pattern on the lower layer side and the alignment mark on the lower layer side as well as the amount of misalignment between the body pattern on the upper layer side and the alignment mark on the upper layer side.

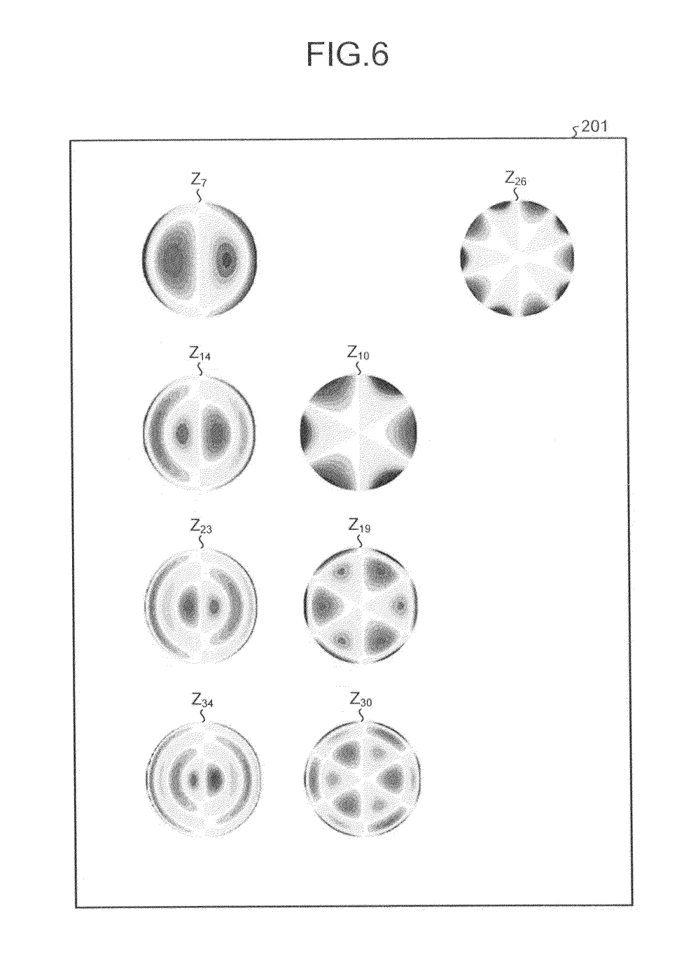

FIG. 6 is a diagram illustrating the Zernike polynomial. Among the Zernike terms Z₁ to Z₈₁ in the Zernike polynomial (circular polynomial), the pattern misalignment is affected by 19 Zernike terms including Z₇, Z₁₀, Z₁₄, Zn₁₉, Z₂₃, Z₂₆, Z₃₀, Z₃₄, Z₃₉, Z₄₃, Z₄₇, Z₅₀, Z₅₄, Z₅₈, Z₆₂, Z₆₇, Z₇₁, Z₇₅, and Z₇₉. A Zernike polynomial group 201 in FIG. 6 illustrates Z₇, Z₁₀, Z₁₄, Z₁₉, Z₂₃, Z₂₆, Z₃₀, and Z₃₄ while omitting the rest of the 19 Zernike terms.

In the present embodiment, the aberration sensitivity of the aberration monitoring pattern 3 is calculated by simulation using a computer or the like. The aberration sensitivity is the amount of misalignment of the wafer pattern with respect to the amount of aberration (the amount of misalignment per 1 milli-lambda). In other words, the aberration sensitivity is the degree indicating how much effect each of the 19 types of Zernike terms has on each of the 19 positions of the aberration monitoring pattern.

The line pattern Lp1 of the aberration monitoring pattern is affected by each of the 19 types of Zernike terms with various levels of aberration sensitivity, for example. When “B1” represents the aberration sensitivity of “Z₇” to the line pattern Lp1, for example, “Z₇” has the effect on the amount of misalignment of the line pattern Lp1 by B1×Z₇.

Moreover, in the present embodiment, the aberration monitoring pattern 3 on the mask 4 is transferred onto the actual wafer W so that the dimension (amount of misalignment) of the aberration monitoring pattern 3 on the wafer is measured. The amount of aberration for each of the 19 types of Zernike terms is then calculated on the basis of the measured amount of misalignment and the calculated aberration sensitivity. Note that the amount of aberration of the 19 types of Zernike terms affecting the pattern misalignment is hereinafter referred to as an amount of aberration Z in some cases.

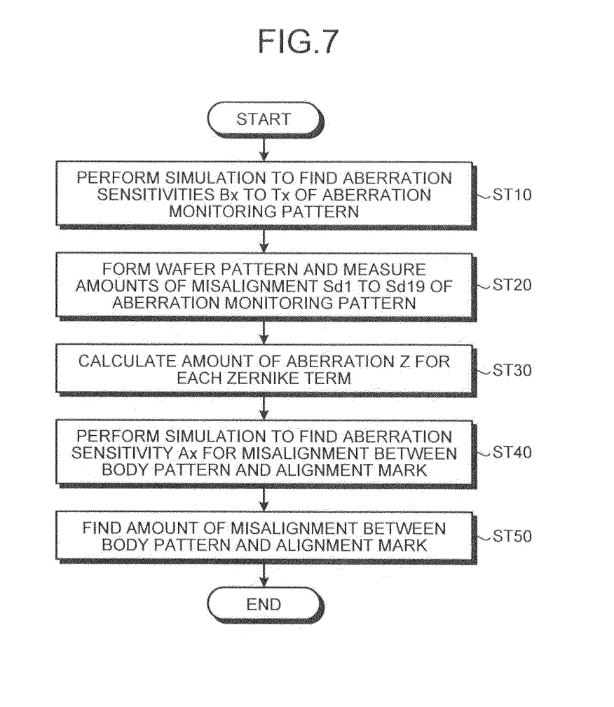

FIG. 7 is a flowchart illustrating the procedure of a process of calculating the amount of misalignment. In the present embodiment, the amount of misalignment between the alignment mark on the lower layer side and the body pattern on the lower layer side is calculated by using a computer or the like. The computer or the like is also used to calculate the amount of misalignment between the alignment mark on the upper layer side and the body pattern on the upper layer side. The computer or the like then calculates the amount of misalignment between the body pattern on the upper layer side and the body pattern on the lower layer side on the basis of the amount of misalignment on the upper layer side and the amount of misalignment on the lower layer side.

Note that the process of calculating the amount of misalignment on the upper layer side and the process of calculating the amount of misalignment on the lower layer side have the same procedure, so that the procedure for the process of calculating the amount of misalignment on the upper layer side will be described in FIG. 7. The amount of aberration onto the mask 4 on the upper layer side of the lithography tool 1 is calculated when calculating the amount of misalignment on the upper layer side. After that, the calculated amount of aberration is used to calculate the amount of misalignment between the body pattern on the upper layer side and the alignment mark 5 on the upper layer side.

When calculating the amount of aberration generated at the time of exposing the upper layer side, aberration sensitivities Bx to Tx (x=1 to 19) of the aberration monitoring pattern 3 are calculated by simulation (step ST10). For example, expressions (1) to (19) are established for the line patterns Lp1 to Lp9 and the space patterns Sp0 to Sp9, respectively.

Note that in the following expressions, each of “Ld1” to “Ld9” indicates the dimension of each of the corresponding line patterns Lp1 to Lp9, and each of “Sd0” to “Sd9” indicates the dimension of each of the corresponding space patterns Sp0 to Sp9. Each of (B1 to B19), (C1 to C19), . . . (T1 to T19) in the following expressions represents the aberration sensitivity. Moreover, the multiplication of the aberration sensitivity and the Zernike term (amount of aberration) such as (B1×Z₇) represents the amount of misalignment of the wafer pattern for this Zernike term.

Ld1=(B1×Z₇)+(B2×Z₁₀)+(B3×Z₁₄)+(B4×Z₁₉)+(B5×Z₂₃)+(B6×Z₂₆)+(B7×Z₃₀)+(B8×Z₃₄)+(B9×Z₃₉)+(B10×Z₄₃)+(B11×Z₄₇)+(B12×Z₅₀)+(B13×Z₅₄)+(B14×Z₅₈)+(B15×Z₆₂)+(B16×Z₆₇)+(B17×Z₇₁)+(B18×Z₇₅)+(B19×Z₇₉) (1)

Ld2−(C1×Z₇)+(C2×Z₁₀)+(C3×Z₁₄)+(C4×Z₁₉)+(C5×Z₂₃)+(C6×Z₂₆)+(C7×Z₃₀)+(C8×Z₃₄)+(C9×Z₃₉)+(C10×Z₄₃)+(C11×Z₄₇)+(C12×Z₅₀)+(C13×Z₅₄)+(C14×Z₅₈)+(C15×Z₆₂)+(C16×Z₆₇)+(C17×Z₇₁)+(C18×Z₇₅)+(C19×Z₇₉) (2)

Ld3=(D1×Z₇)+(D2×Z₁₀)+(D3×Z₁₄)+(D4×Z₁₉)+(D5×Z₂₃)+(D6×Z₂₆)+(D7×Z₃₀)+(D8×Z₃₄)+(D9×Z₃₉)+(D10×Z₄₃)+(D11×Z₄₇)+(D12×Z₅₀)+(D13×Z₅₄)+(D14×Z₅₈)+(D15×Z₆₂)+(D16×Z₆₇)+(D17×Z₇₁)+(D18×Z₇₅)+(D19×Z₇₉) (3)

Ld4=(E1×Z₇)+(E2×Z₁₀)+(E3×Z₁₄)+(E4×Z₁₉)+(E5×Z₂₃)+(E6×Z₂₆)+(E7×Z₃₀)+(E8×Z₃₄)+(E9×Z₃₉)+(E10×Z₄₃)+(E11×Z₄₇)+(E12×Z₅₀)+(E13×Z₅₄)+(E14×Z₅₈)+(E15×Z₆₂)+(E16×Z₆₇)+(E17×Z₇₁)+(E18×Z₇₅)+(E19×Z₇₉) (4)

Ld5=(F1×Z₇)+(F2×Z₁₀)+(F3×Z₁₄)+(F4×Z₁₉)+(F5×Z₂₃)+(F6×Z₂₆)+(F7×Z₃₀)+(F8×Z₃₄)+(F9×Z₃₉)+(F10×Z₄₃)+(F11×Z₄₇)+(F12×Z₅₀)+(F13×Z₅₄)+(F14×Z₅₈)+(F15×Z₆₂)+(F16×Z₆₇)+(F17×Z₇₁)₊₍F18×Z₇₅)+(F19×Z₇₉) (5)

Ld6=(G1×Z₇)+(G2×Z₁₀)+(G3×Z₁₄)+(G4×Z₁₉)+(G5×Z₂₃)+(G6×Z₂₆)+(G7×Z₃₀)+(G8×Z₃₄)+(G9×Z₃₉)+(G10×Z₄₃)+(G11×Z₄₇)+(G12×Z₅₀)+(G13×Z₅₄)+(G14×Z₅₈)+(G15×Z₆₂)+(G16×Z₆₇)+(G17×Z₇₁)+(G18×Z₇₅)+(G19×Z₇₉) (6)

Ld7=(H1×Z₇)+(H2×Z₁₀)+(H3×Z₁₄)+(H4×Z₁₉)+(H5×Z₂₃)+(H6×Z₂₆)+(H7×Z₃₀)+(H8×Z₃₄)+(H9×Z₃₉)+(H10×Z₄₃)+(H11×Z₄₇)+(H12×Z₅₀)+(H13×Z₅₄)+(H14×Z₅₈)+(H15×Z₆₂)+(H16×Z₆₇)+(H17×Z₇₁)+(H18×Z₇₅)+(H19×Z₇₉) (7)

Ld8=(I1×Z₇)+(I2×Z₁₀)+(I3×Z₁₄)+(I4×Z₁₉)+(I5×Z₂₃)+(I6×Z₂₆)+(I7×Z₃₀)+(I8×Z₃₄)+(I9×Z₃₉)+(I10×Z₄₃)+(I11×Z₄₇)+(I12×Z₅₀)+(I13×Z₅₄)+(I14×Z₅₈)+(I15×Z₆₂)+(I16×Z₆₇)+(I17×Z₇₁)+(I18×Z₇₅)+(I19×Z₇₉) (8)

Ld9=(J1×Z₇)+(J2×Z₁₀)+(J3×Z₁₄)+(J4×Z₁₉)+(J5×Z₂₃)+(J6×Z₂₆)+(J7×Z₃₀)+(J8×Z₃₄)+(J9×Z₃₉)+(J10×Z₄₃)+(J11×Z₄₇)+(J12×Z₅₀)+(J13×Z₅₄)+(J14×Z₅₈)+(J15×Z₆₂)+(J16×Z₆₇)+(J17×Z₇₁)+(J18×Z₇₅)+(J19×Z₇₉) (9)

Sd0=(K1×Z₇)+(K2×Z₁₀)+(K3×Z₁₄)+(K4×Z₁₉)+(K5×Z₂₃)+(K6×Z₂₆)+(K7×Z₃₀)+(K8×Z₃₄)+(K9×Z₃₉)+(K10×Z₄₃)+(K11×Z₄₇)+(K12×Z₅₀)+(K13×Z₅₄)+(K14×Z₅₈)+(K15×Z₆₂)+(K16×Z₆₇)+(K17×Z₇₁)+(K18×Z₇₅)+(K19×Z₇₉) (10)

Sd1=(L1×Z₇)+(L2×Z₁₀)+(L3×Z₁₄)+(L4×Z₁₉)+(L5×Z₂₃)+(L6×Z₂₆)+(L7×Z₃₀)+(L8×Z₃₄)+(L9×Z₃₉)+(L10×Z₄₃)+(L11×Z₄₇)+(L12×Z₅₀)+(L13×Z₅₄)+(L14×Z₅₈)+(L15×Z₆₂)+(L16×Z₆₇)+(L17×Z₇₁)+(L18×Z₇₅)+(L19×Z₇₉) (11)

Sd2=(M1×Z₇)+(M2×Z₁₀)+(M3×Z₁₄)+(M4×Z₁₉)+(M5×Z₂₃)+(M6×Z₂₆)+(M7×Z₃₀)+(M8×Z₃₄)+(M9×Z₃₉)+(M10×Z₄₃)+(M11×Z₄₇)+(M12×Z₅₀)+(M13×Z₅₄)+(M14×Z₅₈)+(M15×Z₆₂)+(M16×Z₆₇)+(M17×Z₇₁)+(M18×Z₇₅)+(M19×Z₇₉) (12)

Sd3=(N1×Z₇)+(N2×Z₁₀)+(N3×Z₁₄)+(N4×Z₁₉)+(N5×Z₂₃)+(N6×Z₂₆)+(N7×Z₃₀)+(N8×Z₃₄)+(N9×Z₃₉)+(N10×Z₄₃)+(N11×Z₄₇)+(N12×Z₅₀)+(N13×Z₅₄)+(N14×Z₅₈)+(N15×Z₆₂)+(N16×Z₆₇)+(N17×Z₇₁)+(N18×Z₇₅)+(N19×Z₇₉) (13)

Sd4=(O1×Z₇)+(O2×Z₁₀)+(O3×Z₁₄)+(O4×Z₁₉₎+(O5×Z₂₃)+(O6×Z₂₆)+(O7×Z₃₀)+(O8×Z₃₄)+(O9×Z₃₉)+(O10×Z₄₃)+(O11×Z₄₇)+(O12×Z₅₀)+(O13×Z₅₄)+(O14×Z₅₈)+(O15×Z₆₂)+(O16×Z₆₇)+(O17×Z₇₁) +(O18×Z₇₅)+(O19×Z₇₉) (14)

Sd5=(P1×Z₇)+(P2×Z₁₀)+(P3×Z₁₄)+(P4×Z₁₉+(P5×Z₂₃)+(P6×Z₂₆)+(P7×Z₃₀)+(P8×Z₃₄)+(P9×Z₃₉)+(P10×Z₄₃)+(P11×Z₄₇)+(P12×Z₅₀)+(P13×Z₅₄)+(P14×Z₅₈)+(P15×Z₆₂)+(P16×Z₆₇)+(P17×Z₇₁)+(P18×Z₇₅)+(P19×Z₇₉) (15)

Sd6=(Q1×Z₇)+(Q2×Z₁₀)+(Q3×Z₁₄)+(Q4×Z₁₉)+(Q5×Z₂₃)+(Q6×Z₂₆)+(Q7×Z₃₀)+(Q8×Z₃₄)+(Q9×Z₃₉)+(Q10×Z₄₃)+(Q11×Z₄₇)+(Q12×Z₅₀)+(Q13×Z₅₄)+(Q14×Z₅₈)+(Q15×Z₆₂)+(Q16×Z₆₇)+(Q17×Z₇₁)+(Q18×Z₇₅)+(Q19×Z₇₉) (16)

Sd7=(R1×Z₇)+(R2×Z₁₀)+(R3×Z₁₄)+(R4 ×Z₁₉)+(R5×Z₂₃)+(R6×Z₂₆)+(R7×Z₃₀)+(R8×Z₃₄)+(R9×Z₃₉)+(R10×Z₄₃)+(R11×Z₄₇)+(R12×Z₅₀)+(R13×Z₅₄)+(R14×Z₅₈)+(R15×Z₆₂)+(R16×Z₆₇)+(R17×Z₇₁) +(R18 ×Z₇₅)+(R19×Z₇₉) (17)

Sd8=(S1×Z₇)+(S2×Z₁₀)+(S3×Z₁₄)+(S4×Z₁₉)+(S5×Z₂₃)+(S6×Z₂₆)+(S7×Z₃₀)+(S8×Z₃₄)+(S9×Z₃₉)+(S10×Z₄₃)+(Sll×Z₄₇)+(S12×Z₅₀)+(S13×Z₅₄)+(S14×Z₅₈)+(S15×Z₆₂)+(S16×Z₆₇)+(S17×Z₇₁) +(S18×Z₇₅)+(S19×Z₇₉) (18)

Sd9=(T1×Z₇)+(T2×Z₁₀)+(T3×Z₁₄)+(T4×Z₁₉)+(T5×Z₂₃)+(T6×Z₂₆)+(T7×Z₃₀)+(T8×Z₃₄)+(T9×Z₃₉)+(T10×Z₄₃)+(T11×Z₄₇)+(T12×Z₅₀)+(T13×Z₅₄)+(T14×Z₅₈)+(T15×Z₆₂)+(T16×Z₆₇)+(T17×Z₇₁)+(T18×Z₇₅)+(T19×Z₇₉) (19)

Here, the procedure of the process of calculating the aberration sensitivity will be described. In finding the aberration sensitivity for the line pattern Lp1, for example, there is calculated a first amount of misalignment with which it is assumed that there is no effect of aberration in the lithography tool 1. The first amount of misalignment is the amount of misalignment of the line pattern Lp1 (wafer pattern) when it is assumed that there is no effect of aberration.

There is also calculated a second amount of misalignment, with which it is assumed that there is an effect of aberration by only “Z₇” in the lithography tool 1 but no effect by the other Zernike terms (the other Zernike terms=0). The second amount of misalignment is the amount of misalignment of the line pattern Lp1 when it is assumed that there is the effect of aberration by only “Z₇”. When calculating the second amount of misalignment, a value of the Zernike term Z₇ (X milli-lambda) (X is an arbitrary value) is input to a pupil function of the pupil surface 62.

A difference (S1) between the first amount of misalignment and the second amount of misalignment is calculated once the first and second amounts of misalignment are calculated. This difference corresponds to the multiplication of the aberration sensitivity (B1) of the line pattern Lp1 to “Z₇” (X milli-lambda) and “Z₇” (the amount of misalignment caused by “Z₇”).

Accordingly, the value of the aberration sensitivity (S1/Z₇=B1) can be calculated on the basis of the calculated difference and the input milli-lambda value. Each of the aberration sensitivities B2 to B19 is calculated by the similar method. The aberration sensitivity B×(x=1 to 19) for the aberration monitoring pattern 3 is calculated as described above. By the similar method, each of aberration sensitivities Cx, Dx, . . . Tx is calculated as well.

The mask 4 is used to form the actual wafer pattern on the wafer W. At this time, the lithography tool 1 is used to expose the wafer W onto which the resist is applied. The wafer pattern that is a resist pattern is formed by developing the wafer W. Within the wafer pattern being formed, each of amounts of misalignment Sd1 to Sd19 of the aberration monitoring pattern 3 is measured (step ST20).

Specifically, the amount of misalignment of the line patterns Lp1 to Lp9 and the space patterns Sp0 to Sp9 is measured by using an SEM (Scanning Electron Microscope) or the like. Note that the aberration monitoring pattern 3 may also be arranged symmetrically about the line pattern 100 on the mask 4. In this case, the amounts of misalignment Sd1 to Sd19 of the aberration monitoring pattern 3 may be calculated on the basis of a dimensional difference (amount of dimensional gap) between the dimension of the aberration monitoring pattern 3 on the left side and the dimension of the aberration monitoring pattern 3 on the right side.

The 19 simultaneous equations (the aforementioned expressions (1) to (19)) are established after completing the calculation of the aberration sensitivities Bx to Tx and the measurement of the amounts of misalignment Sd1 to Sd19. Then, the simultaneous equation is solved to calculate the amount of aberration Z of each Zernike term (step ST30). The amount of aberration Z of each of the 19 types of Zernike terms is calculated in the present embodiment.

Moreover, aberration sensitivity Ax related to the misalignment between the body pattern and the alignment mark 5 is calculated by simulation (step ST40). The aberration sensitivity Ax related to the misalignment is calculated by the process similar to that performed in finding the aberration sensitivity Bx.

Subsequently, the amount of misalignment between the body pattern and the alignment mark 5 is calculated on the basis of each amount of aberration Z and the aberration sensitivity Ax related to the misalignment between the body pattern and the alignment mark 5 (step ST50). In this case, expression (20) is established where “D” represents the amount of misalignment between the body pattern and the alignment mark 5.

D=(A1×Z₇)+(A2×Z₁₀)+(A3×Z₁₄)+(A4×Z₁₉)+(A5×Z₂₃)+(A6×Z₂₆)+(A7×Z₃₀)+(A8×Z₃₄)+(A9×Z₃₉)+(A10×Z₄₃)+(A11×Z₄₇)+(A12×Z₅₀)+(A13×Z₅₄)+(A14×Z₅₈)+(A15×Z₆₂)+(A16×Z₆₇)+(A17×Z₇₁)+(A18×Z₇₅)+(A19×Z₇₉) (20)

Accordingly, the amount of misalignment D between the body pattern and the alignment mark 5 is calculated by substituting the calculated value into the aberration sensitivity Ax (A1 to A19) and each amount of aberration Z in expression (20). Note that the amount of aberration Z and the amount of misalignment D are calculated for each of the X direction and the Y direction according to the flowchart illustrated in FIG. 7.

The process in either step ST10 or ST20 may be performed first. Moreover, the process in step ST40 may be performed before the process in each of steps ST10 to ST30 or concurrently with the process in each of steps ST10 to ST30. Furthermore, the configuration of the aberration monitoring pattern 3 is not limited to the configuration illustrated in FIG. 4.

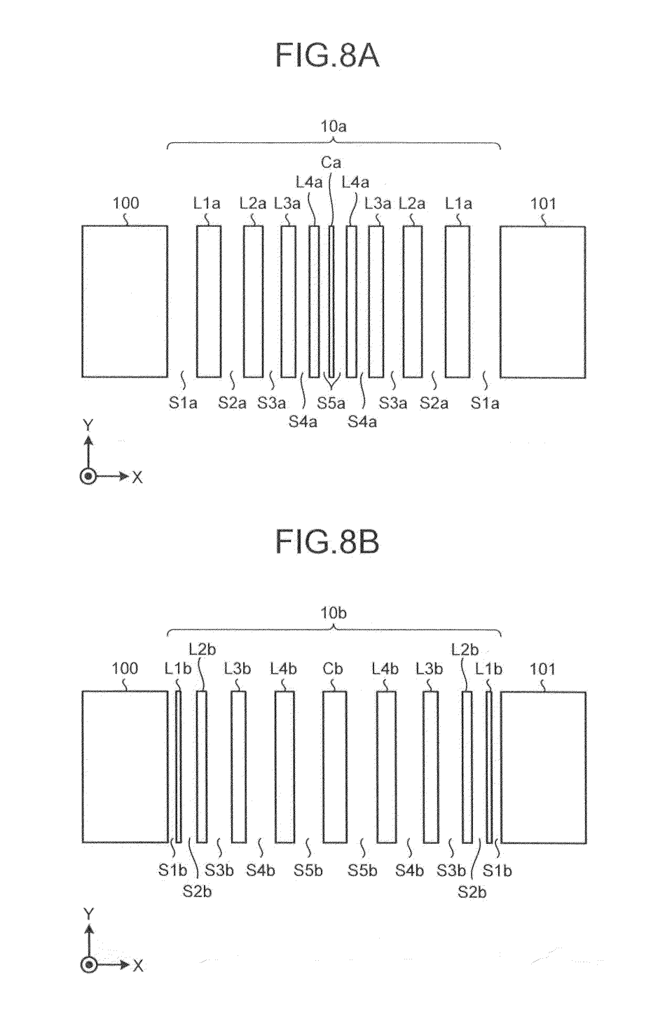

FIGS. 8A and 8B are diagrams each illustrating another configuration example of the aberration monitoring pattern. FIG. 8A illustrates a configuration of an aberration monitoring pattern 10a, while FIG. 8B illustrates a configuration of an aberration monitoring pattern 10b.

The aberration monitoring pattern 10a includes line patterns L1a to L4a, Ca, and L4a to L1a instead of the line patterns Lp1 to Lp9. The aberration monitoring pattern 10a also includes space patterns S1a to S5a and S5a to S1a instead of the space patterns Sp0 to Sp9.

The aberration monitoring pattern 10a is arranged such that a period (cycle) of arrangement of a pair of the line pattern and the space pattern becomes shorter toward the center. Specifically, the aberration monitoring pattern 10a is arranged such that the patterns are symmetrically placed side by side about the line pattern Ca as an axis of symmetry. Within the aberration monitoring pattern 10a, the line patterns L1a to L4a are arranged on the left side of the line pattern Ca, while the line patterns L4a to L1a are arranged on the right side of the line pattern Ca.

The line patterns L1a to L4a and Ca are made thinner in the order of the line pattern L1a, the line pattern L2a, the line pattern L3a, the line pattern L4a, and the line pattern Ca.

Moreover, the line patterns Ca and L4a to L1a are made thicker in the order of the line pattern Ca, the line pattern L4a, the line pattern L3a, the line pattern L2a, and the line pattern L1a.

In the aberration monitoring pattern 10a, moreover, the space patterns S1a to S5a are arranged on the left side of the line pattern Ca, while the space patterns S5a to S1a are arranged on the right side of the line pattern Ca.

The space patterns S1a to S5a are made narrower in the order of the space pattern S1a, the space pattern S2a, the space pattern S3a, the space pattern S4a, and the space pattern S5a.

Moreover, the space patterns S5a to S1a are made wider in the order of the space pattern S5a, the space pattern S4a, the space pattern S3a, the space pattern S2a, and the space pattern S1a.

On the other hand, the aberration monitoring pattern 10b is arranged such that the period of arrangement of a pair of the line pattern and the space pattern becomes longer toward the center. Specifically, the aberration monitoring pattern 10b includes line patterns L1b to L4b, Cb, and L4b to L1b instead of the line patterns Lp1 to Lp9. The aberration monitoring pattern 10b also includes space patterns S1b to S5b and S5b to S1b instead of the space patterns Sp0 to Sp9.

The aberration monitoring pattern 10b is arranged such that the patterns are symmetrically placed side by side about the line pattern Cb as an axis of symmetry. Within the aberration monitoring pattern 10b, the line patterns L1b to L4b are arranged on the left side of the line pattern Cb, while the line patterns L4b to L1b are arranged on the right side of the line pattern Cb.

The line patterns L1b to L4b and Cb are made thicker in the order of the line pattern L1b, the line pattern L2b, the line pattern L3b, the line pattern L4b, and the line pattern Cb.

Moreover, the line patterns Cb and L4b to L1b are made thinner in the order of the line pattern Cb, the line pattern L4b, the line pattern L3b, the line pattern L2b, and the line pattern L1b.

In the aberration monitoring pattern 10b, moreover, the space patterns S1b to S5b are arranged on the left side of the line pattern Cb, while the space patterns S5b to S1b are arranged on the right side of the line pattern Cb.

The space patterns S1b to S5b are made wider in the order of the space pattern S1b, the space pattern S2b, the space pattern S3b, the space pattern S4b, and the space pattern S5b.

Moreover, the space patterns S5b to S1b are made narrower in the order of the space pattern S5b, the space pattern S4b, the space pattern S3b, the space pattern S2b, and the space pattern S1b.

The pair of the line pattern and the space pattern of the aberration monitoring pattern 3 in FIG. 4 is arranged in a predetermined period. The aberration detection sensitivity (misalignment sensitivity) gets higher as the period gets shorter in such aberration monitoring pattern 3 where the line patterns Lp1 to Lp9 and the space patterns Sp0 to Sp9 are arranged in the same period (pattern arrangement period). Within the aberration monitoring pattern 3, moreover, the pattern arranged in the outer region has higher aberration detection sensitivity of a low-order Zernike term, whereas the pattern arranged in the inner region has higher aberration detection sensitivity of a high-order Zernike term.

In the aberration monitoring pattern 10a illustrated in FIG. 8A, the line patterns L1a to L4a and Ca and the space patterns S1a to S5a are arranged such that the period gets shorter toward the inner side (the line pattern Ca). In this case, within the aberration monitoring pattern 10a, the pattern arranged in the outer region has moderate aberration detection sensitivity of the low-order Zernike term, whereas the pattern arranged in the inner region has very high aberration detection sensitivity of the high-order Zernike term.

In other words, within the aberration monitoring pattern 10a, the pattern arranged in the region inside a predetermined position has higher aberration detection sensitivity for the Zernike term than the pattern in the aberration monitoring pattern 3 does.

In the aberration monitoring pattern 10b illustrated in FIG. 8B, the line patterns L1b to L4b and Cb and the space patterns S1b to S5b are arranged such that the period gets shorter toward the outer side (the line patterns 100 and 101). In this case, within the aberration monitoring pattern 10b, the pattern arranged in the inner region has moderate aberration detection sensitivity of the high-order Zernike term, whereas the pattern arranged in the outer region has very high aberration detection sensitivity of the low-order Zernike term.

In other words, within the aberration monitoring pattern 10b, the pattern arranged in the region outside a predetermined position has higher aberration detection sensitivity for the Zernike term than the pattern in the aberration monitoring pattern 3 does.

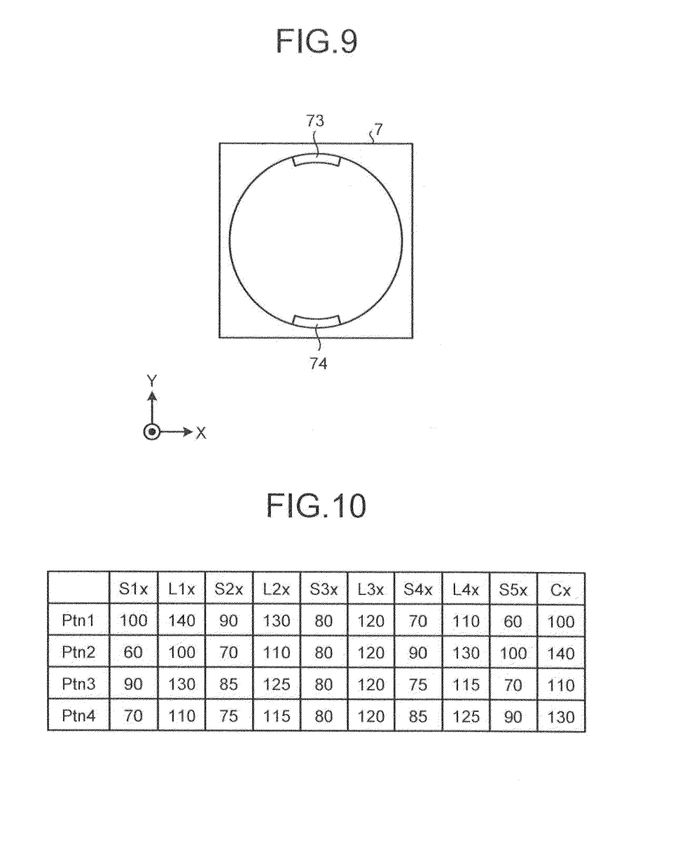

Next, the lighting of the lithography tool 1 will be described. FIG. 9 is a diagram illustrating the form of the lighting included in the lithography tool. Lighting 7 included in the lithography tool 1 is dipole lighting 73 and 74, for example. The dipole lighting 73 and 74 is a light source arranged in parallel with a Y direction and formed of a portion of a ring shape, for example.

In the present embodiment, for example, the aberration monitoring pattern 3 illustrated in FIG. 4 or the aberration monitoring patterns 10a and 10b illustrated in FIGS. 8A and 8B is used for the lighting 7. An optical image I (x) formed on the wafer W when the wafer W is irradiated with the exposure light by the lithography tool 1 is expressed by expression (21) below, for example.

[Expression 1]

I(x)=∫γ(s)|∫ã(f−s)p(f)e^{-2πixf}df|²ds (21)

Expression (21) is an Abbe Formulation which performs display of a light source area. A portion “r (s)” in expression (21) is the portion resulting from the lighting 7 (the light source). Note that the form of the lighting 7 is not limited to what is illustrated in FIG. 9. The configuration of the aberration monitoring pattern is not limited to the configuration of the aberration monitoring patterns 3, 10a, and 10b, either.

FIG. 10 is a diagram illustrating an example of the dimension of the aberration monitoring pattern. FIG. 10 illustrates the example of the dimension of the aberration monitoring pattern such as the aberration monitoring patterns 10a and 10b. Aberration monitoring patterns Ptn1 to Ptn4 illustrate first to fourth examples of the dimension, respectively.

In the diagram, “S1x” indicates the dimension of the space patterns S1a, S1b, and the like. Likewise, “S2x” indicates the dimension of the space patterns S2a, S2b, and the like, and “S3x” indicates the dimension of the space patterns S3a, S3b, and the like. Moreover, “S4x” indicates the dimension of the space patterns S4a, S4b, and the like, and “S5x” indicates the dimension of the space patterns S5a, S5b, and the like.

Moreover, “L1x” indicates the dimension of the line patterns L1a, L1b, and the like, “L2x” indicates the dimension of the line patterns L2a, L2b, and the like, “L3x” indicates the dimension of the line patterns L3a, L3b, and the like, and “L4x” indicates the dimension of the line patterns L4a, L4b, and the like. Furthermore, “Cx” indicates the dimension of the line patterns Ca, Cb, and the like.

In the aberration monitoring pattern Ptn1, for example, “S1x”, “S2x”, “S3x”, “S4x”, and “S5x” have dimensions equal to 100 nm, 90 nm, 80 nm, 70 nm, and 60 nm, respectively. Moreover, in the aberration monitoring pattern Ptn1, “L1x”, “L2x”, “L3x”, “L4x”, and “Cx” have dimensions equal to 140 nm, 130 nm, 120 nm, 110 nm, and 100 nm, respectively.

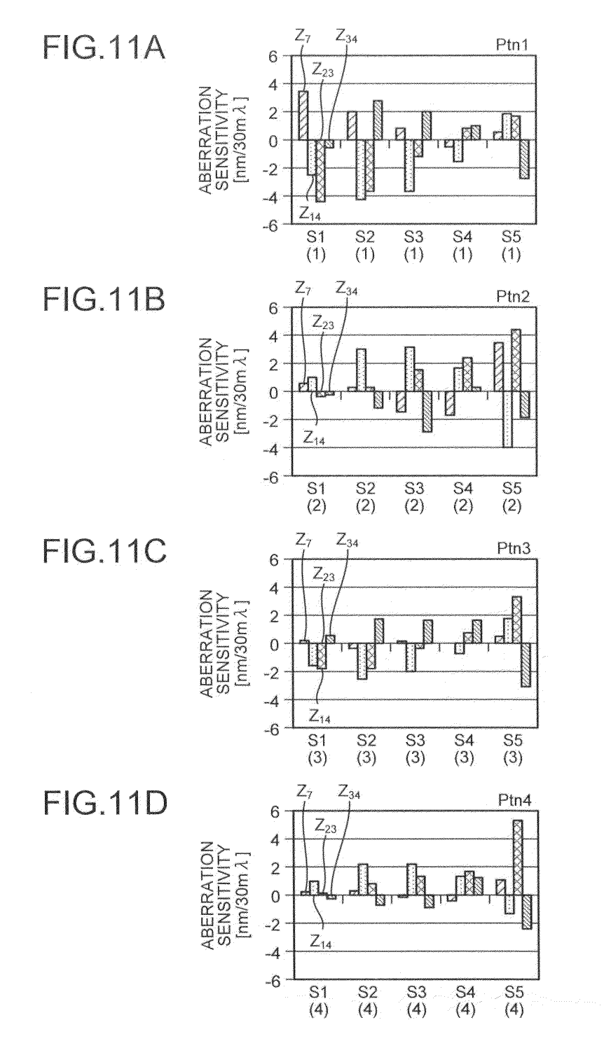

FIGS. 11A to 11D are diagrams illustrating the aberration sensitivity for each pattern. Each of FIGS. 11A to 11D illustrates the aberration sensitivity for each of the aberration monitoring patterns (Ptn1 to Ptn4) illustrated in FIG. 10. Note that FIGS. 11A to 11D illustrate the aberration sensitivity of “Z₇”, “Z₁₄”, “Z₂₃” and “Z₃₄” out of the 19 types of aberration sensitivities (Zernike terms).

FIG. 11A illustrates the aberration sensitivity of “S1 (1)” to “S5 (1)” corresponding to “S1x” to “S4x” of “Ptn1”, out of the aberration monitoring patterns of “Ptn1”. FIG. 11B illustrates the aberration sensitivity of “S1 (2)” to “S5 (2)” corresponding to “S1x” to “S4x” of “Ptn2”, out of the aberration monitoring patterns of “Ptn2”. FIG. 11C illustrates the aberration sensitivity of “S1 (3)” to “S5 (3)” corresponding to “S1x” to “S4x” of “Ptn3”, out of the aberration monitoring patterns of “Ptn3”. FIG. 11D illustrates the aberration sensitivity of “S1 (4)” to “S5 (4)” corresponding to “S1x” to “S4x” of “Ptn4”, out of the aberration monitoring patterns of “Ptn4”. As illustrated in FIGS. 11A to 11D, the aberration sensitivity of each of “S1x” to “S4x” varies in “Ptn1” to “Ptn4”, whereby satisfactory aberration sensitivity can be obtained.

The amount of aberration Z of each Zernike term is calculated for each type of the lighting 7, each type of the mask 4 (mask pattern), and each lithography tool 1. The amount of aberration Z of each Zernike term is calculated for each layer in the wafer process when manufacturing the semiconductor device, for example.

Then, the amount of aberration Z of each Zernike term is used to calculate the amount of misalignment between the body pattern and the alignment mark 5 of the pattern on the lower layer side as well as the amount of misalignment between the body pattern and the alignment mark 5 of the pattern on the upper layer side. The calculated amount of misalignment is used thereafter to perform alignment of the body pattern on the upper layer side and the lower layer side when the lithography tool 1 is used to form the pattern on the upper layer side on top of the pattern on the lower layer side.

In manufacturing the semiconductor device, the lithography tool 1 uses the mask 4 to expose the wafer (such as a product mask) onto which the resist is applied after the alignment of the body pattern on the upper layer side and the lower layer side is performed. The wafer is developed thereafter so that the resist pattern is formed on the wafer. Then, the resist pattern is used as the mask to perform etching on a lower layer film of the resist pattern. As a result, an actual pattern corresponding to the resist pattern is formed on the wafer. The calculation of the amount of aberration Z, the calculation of the amount of misalignment, the exposure processing performed after the alignment using the amount of misalignment as well as the subsequent developing process and the etching process are repeated for each layer in manufacturing the semiconductor device.

Note that while there has been described the case in the present embodiment where the amount of aberration Z is used to perform the alignment of the body pattern on the upper layer side and the lower layer side, the amount of aberration Z may be used to perform an aberration correction of the lithography tool 1 as well. In this case, the amount of aberration Z is calculated at a predetermined timing, so that the calculated amount of aberration Z is used to perform the aberration correction of the lithography tool 1.

Moreover, the body pattern and the alignment mark need not be formed as the mask pattern on the mask 4 that is used to calculate the amount of aberration Z. In other words, any mask may be used to calculate the amount of aberration Z as long as the aberration monitoring pattern is formed as the mask pattern on the mask.

Moreover, the amount of misalignment between the body pattern and the alignment mark 5 may be calculated by using a mask pattern (design data) of another mask different from the mask 4. In other words, the amount of misalignment between the body pattern and the alignment mark 5 may be calculated by using the amount of aberration Z for each type of mask. The mask used in calculating the amount of aberration Z may be different from the mask used in calculating the amount of misalignment between the body pattern and the alignment mark 5.

While there has been described the case in the present embodiment where the amount of aberration and the aberration sensitivity for all the 19 types of Zernike terms are calculated, the amount of aberration and the aberration sensitivity may be calculated for 18 or fewer types of Zernike terms as well. In other words, the Zernike term need only include at least one of the Zernike terms affecting the pattern misalignment within the Zernike polynomial.

According to the embodiments described above, the amount of aberration Z can be found easily and accurately because the amount of aberration Z is calculated on the basis of the aberration sensitivity of the aberration monitoring pattern calculated by simulation and the amount of misalignment of the aberration monitoring pattern 3 formed on the actual wafer W.

Moreover, the amount of misalignment can be found easily and accurately because the amount of misalignment between the body pattern and the alignment mark 5 is calculated by using the amount of aberration Z that is calculated accurately. At the same time, the amount of misalignment between the upper and lower layers can be found easily and accurately because the amount of misalignment between the body pattern on the upper layer side and the body pattern on the lower layer side is calculated on the basis of the amount of misalignment on the lower layer side and the amount of misalignment on the upper layer side that are calculated accurately.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of calculating an amount of aberration, the method comprising:
performing a simulation to calculate, for each Zernike term, aberration sensitivity of an aberration that is generated on a substrate when a lithography tool performs exposure processing on the substrate by using a mask on which a mask pattern is formed;
forming a substrate pattern corresponding to the mask pattern on the substrate by using the lithography tool;
measuring an amount of misalignment of the substrate pattern; and
calculating the amount of aberration for each Zernike term on the basis of the aberration sensitivity and the amount of misalignment.

2. The method of calculating an amount of aberration according to claim 1, wherein the mask pattern is a pattern in which a pair of a line pattern and a space pattern is arranged in a predetermined period.

3. The method of calculating an amount of aberration according to claim 1, further comprising:
using each of the aberration sensitivity and the amount of misalignment that is the same in number as the number of terms of the Zernike term for which the amount of aberration is to be calculated, and creating a simultaneous equation including expressions that are the same in number as the number of terms; and
calculating the amount of aberration for each Zernike term by solving the simultaneous equation.

4. The method of calculating an amount of aberration according to claim 2, wherein the mask pattern is a pattern in which the pair of the line pattern and the space pattern is arranged in a period that gets shorter toward a center.

5. The method of calculating an amount of aberration according to claim 2, wherein the mask pattern is a pattern in which the pair of the line pattern and the space pattern is arranged in a period that gets longer toward a center.

6. The method of calculating an amount of aberration according to claim 1, wherein the Zernike term includes at least one of Zernike terms that have an effect on the misalignment of the substrate pattern within a Zernike polynomial.

7. The method of calculating an amount of aberration according to claim 6, wherein the Zernike term corresponds to 19 types of Zernike terms that have the effect on the misalignment of the substrate pattern within the Zernike polynomial.

8. The method of calculating an amount of aberration according to claim 2, wherein the pair of the line pattern and the space pattern is arranged between a first line pattern thicker than the line pattern and the space pattern, and a second line pattern thicker than the line pattern and the space pattern.

9. The method of calculating an amount of aberration according to claim 2, wherein the pair of the line pattern and the space pattern is arranged symmetrically about a third line pattern that is thicker than the line pattern and the space pattern.

10. The method of calculating an amount of aberration according to claim 1, wherein the mask pattern is a pattern in which nine line patterns and 10 space patterns are arranged.

11. A method of calculating an amount of misalignment, the method comprising:
performing a first simulation to calculate, for each Zernike term, first aberration sensitivity of an aberration that is generated on a first substrate when a lithography tool performs exposure processing on the first substrate by using a first mask on which a first mask pattern is formed;
forming a first substrate pattern corresponding to the first mask pattern on the first substrate by using the lithography tool;
measuring an amount of misalignment of the first substrate pattern;
calculating the amount of aberration for each Zernike term on the basis of the first aberration sensitivity and the amount of misalignment;
performing a second simulation to calculate second aberration sensitivity related to an amount of misalignment that is generated between an alignment mark on a second substrate and a body pattern on the second substrate when the lithography tool performs exposure processing on the second substrate by using a second mask on which an alignment mark serving as a second mask pattern used in an alignment between layers and a body pattern serving as a third mask pattern are formed; and
calculating the amount of misalignment between the alignment mark and the body pattern transferred onto the second substrate on the basis of the second aberration sensitivity and the amount of aberration.

12. The method of calculating an amount of misalignment according to claim 11, wherein
the amount of misalignment corresponds to a first amount of misalignment for a first layer formed on the second substrate, and a second amount of misalignment for a second layer to be formed on the second substrate, and
an amount of misalignment between a body pattern on the first layer and a body pattern on the second layer is calculated on the basis of the first and second amounts of misalignment.

13. The method of calculating an amount of misalignment according to claim 11, wherein the first mask pattern is a pattern in which a pair of a line pattern and a space pattern is arranged in a predetermined period.

14. The method of calculating an amount of misalignment according to claim 11, further comprising:
using each of the aberration sensitivity and the amount of misalignment that is the same in number as the number of terms of the Zernike term for which the amount of aberration is to be calculated, and creating a simultaneous equation including expressions that are the same in number as the number of terms; and
calculating the amount of aberration for each Zernike term by solving the simultaneous equation.

15. The method of calculating an amount of misalignment according to claim 13, wherein the first mask pattern is a pattern in which the pair of the line pattern and the space pattern is arranged in a period that gets shorter toward a center.

16. The method of calculating an amount of misalignment according to claim 13, wherein the first mask pattern is a pattern in which the pair of the line pattern and the space pattern is arranged in a period that gets longer toward a center.

17. The method of calculating an amount of misalignment according to claim 11, wherein the Zernike term includes at least one of Zernike terms that have an effect on the misalignment of the first substrate pattern within a Zernike polynomial.

18. The method of calculating an amount of misalignment according to claim 17, wherein the Zernike term corresponds to 19 types of Zernike terms that have the effect on the misalignment of the first substrate pattern within the Zernike polynomial.

19. The method of calculating an amount of misalignment according to claim 13, wherein the pair of the line pattern and the space pattern is arranged between a first line pattern thicker than the line pattern and the space pattern, and a second line pattern thicker than the line pattern and the space pattern.

20. The method of calculating an amount of misalignment according to claim 13, wherein the pair of the line pattern and the space pattern is arranged symmetrically about a third line pattern that is thicker than the line pattern and the space pattern.
